(19) United States
(12) Patent Application Publication
(10) Pub. No.: US 2026/0231720 A1
(43) Pub. Date: Aug. 6, 2026

(54) SEALING METHODS AND APPARATUSES

(71) Applicant: Taiwan Semiconductor Manufacturing Company, Ltd., Hsinchu (TW)

(72) Inventors: Tzu Jian TSENG, Hsinchu (TW); Kuang-Wei CHENG, Hsinchu (TW); Yung-Tsun LIU, Hsinchu (TW)

(73) Assignee: Taiwan Semiconductor Manufacturing Company, Ltd., Hsinchu (TW)

(21) Appl. No.: 19/044,104

(22) Filed: Feb. 3, 2025

(51) Int. Cl. H01L 21/67; H01L 21/56

(52) U.S. Cl. CPC H10P 72/0441; H10W 74/01

(57) ABSTRACT

A sealing apparatus is provided. The sealing apparatus includes a wafer stage configured to hold a stack of wafers on the wafer stage and a nozzle arranged at a side of the wafer stage and configured to direct a sealant flow to a side surface of the stack of wafers. The sealing apparatus further includes a gas purger arranged at the side of the wafer stage and configured to direct a purge gas flow toward a backside surface of the stack of wafers.

### BACKGROUND

Wafer bevel sealing is an important process to protect wafer edges and prevent particle contamination on the wafer surfaces adjacent the edges. A sealing nozzle may be used to spray a polymer sealant to the wafer bevel via jet nozzles. However, the polymer sealant particles may also be deposited on the main surface of the wafers adjacent the wafer bevel during the process. In particular, the polymer sealant particles may be deposited on the backside surface of the wafers. These sealant particles increase the defect rate of wafer products during the fabrication process. It is, therefore, desirable to prevent the sealant particle contamination near the wafer edges. Thus, improved sealing apparatus and methods for reducing the contaminant particles on the wafer surfaces adjacent the edges are desirable.

### BRIEF DESCRIPTION OF THE DRAWING

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a schematic view of a sealing apparatus in accordance with some embodiments of the present disclosure.

FIG. 2A illustrates a front view of a gas purger in accordance with some embodiments of the present disclosure.

FIG. 2B illustrates a side view of a gas purger in accordance with some embodiments of the present disclosure.

FIG. 2C illustrates a top view of a gas purger in accordance with some embodiments of the present disclosure.

FIG. 3 illustrates a perspective view of a head portion of a gas purger in accordance with some embodiments of the present disclosure.

FIG. 4 illustrates a side view of a base portion of a gas purger in accordance with some embodiments of the present disclosure.

FIG. 5 illustrates a close-up view of a portion of a sealing apparatus in accordance with some embodiments of the present disclosure.

FIG. 6 illustrates a flow field concentration distribution map in accordance with some embodiments of the present disclosure.

FIG. 7 illustrates a flow diagram of a method for manufacturing a semiconductor device in accordance with some embodiments of the present disclosure.

FIGS. 8A and 8B illustrate a computer system for implementing various methods in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

Wafer bevel sealing using a polymer sealant protects the wafer edge and prevents edge chipping and particle contamination on the wafer edges. However, the polymer sealant particles may be deposited on the backside surface of the wafers during the sealing process. Embodiments of this disclosure provide an improved apparatus and methods for manufacturing a semiconductor device, thereby reducing the polymer sealant particle contamination on the backside surface of the wafers. In some embodiments, the improved apparatuses and methods include using a gas purge module to prevent the polymer sealant particles from depositing on the backside surface of the wafers, thereby reducing the contamination on the backside surface of the wafers. Consequently, the defect rate of wafer products can be reduced, and the quality of the wafer product can be improved.

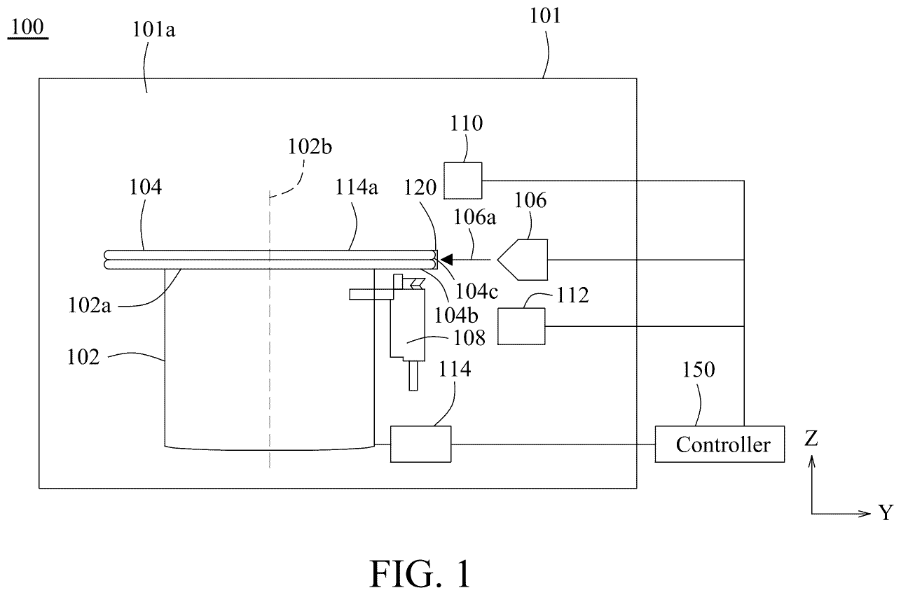

FIG. 1 illustrates a schematic view of a sealing apparatus 100 in accordance with some embodiments of the present disclosure. In some embodiments, the sealing apparatus 100 includes a wafer stage 102, a sealant nozzle 106, and a gas purger 108.

In some embodiments, the wafer stage 102 includes a wafer platform 102a. The wafer platform 102a is configured to hold a stack of wafers 104 on the wafer platform 102a. In some examples, the wafer platform 102a is configured to hold a wafer on the wafer platform 102a. In some examples, the wafer platform 102a is configured to hold a stack of wafers 104 on the wafer platform 102a. The wafer platform 102a is configured to rotate on the wafer stage 102, such that the stack of wafers 104 on the wafer platform 102a are able to rotate along an axis 102b of the wafer stage 102 and the sealant nozzle 106 can sweep across a side surface 104c of the stack of wafers 104. Although two wafers of the stack of wafers 104 are shown in FIG. 1, any suitable number of wafers can be included in the stack of wafers 104. In some embodiments, the stack includes only one wafer.

In some embodiments, the stack of wafers 104 includes at least two wafers stacked vertically. In some embodiments, each of the at least two wafers has the same diameter, such that the at least two wafers can be stacked together.

In some embodiments, the sealant nozzle 106 is arranged on a side of the wafer stage 102. In some embodiments, the sealant nozzle 106 is aligned with the stack of wafers 104 horizontally, such that the sealant nozzle 106 can direct a sealant flow 106a from the sealant nozzle 106 toward the side surface 104c of the stack of wafers 104. For example, the sealant nozzle 106 is aligned with the stack of wafers 104 in the y direction. In some embodiments, the sealant nozzle 106 is mounted to a fixture (not shown) of the sealing apparatus 100, such that the sealant nozzle 106 is supported by the fixture.

In some embodiments, the sealant nozzle 106 is at the same vertical level as the stack of wafers 104 to minimize the amount of the sealant particles deposited on the backside surface 104b of the stack of wafers 104 and the frontside surface 104a of the stack of wafers 104.

In some embodiments, the sealant flow 106a is generated by a pump (not shown). In some embodiments, the flow rate of the sealant flow 106a is adjustable by the pump. In some embodiments, the sealant flow 106a includes a sealant mist. In some embodiments, the sealant flow 106a includes sealant droplets. In some embodiments, the sealant flow 106a includes a dielectric material for wafer bonding. In some embodiments, the sealant flow 106a includes polymer sealant particles. In some embodiments, the polymer sealant particles includes a polyimide, a polybenzoxazole, and/or epoxy resins. In some embodiments, the polymer sealant particles include silicone-based polymers.

In some embodiments, the sealant nozzle 106 is a jet nozzle configured to increase the sealant flow 106a rate at the nozzle opening.

In some embodiments, a sealing layer 120 is formed on the side surface 104c of the stack of wafers 104 after sealant particles from the sealant flow 106a are deposited on the side surface 104c of the stack of wafers 104. In some embodiments, the sealing layer 120 seals the bevel edge of the stack of wafers 104 to protect the bevel edge of the stack of wafers 104 from edge chipping.

In some embodiments, the wafer stage 102 is driven to move toward and/or away from the sealant nozzle 106. In some embodiments, the wafer stage 102 is driven to move vertically to align the stack of wafers 104 with the sealant nozzle 106. Additionally or alternatively, in some embodiments, the sealant nozzle 106 is driven to move toward and/or away from the wafer stage 102. In some embodiments, the wafer stage is driven along tracks (not shown) to move horizontally and vertically.

In some embodiments, the gas purger 108 is arranged on the side of the wafer stage 102. In some embodiments, the gas purger 108 is mounted on the wafer stage 102.

In some embodiments, the gas purger 108 includes a gas diffusion channel configured to spray a purge gas flow towards the backside surface 104b of the stack of wafers 104 to prevent the sealant particles from depositing on the backside surface 104b of the stack of wafers 104.

In some embodiments, the purge gas is N₂. In some embodiments, the purge gas is an inert gas, such as He and Ar.

In some embodiments, the gas purger 108 further includes a plurality of holes configured to provide a vacuum to remove the sealant particles that are not deposited on the side surface 104c of the stack of the wafers 104. In some embodiments, the plurality of holes are also configured to remove the purge gas from the sealing apparatus 100.

In some embodiments, the sealing apparatus 100 further includes an imager 110 arranged adjacent to the sealant nozzle 106, the gas purger 108, and the wafer stage 102. In some embodiments, the imager 110 is a charge-coupled device (CCD) camera configured to capture an image of the sealant nozzle 106, the gas purger 108, and the stack of wafers 104 on the wafer stage 102. In some embodiments, the imager 110 is configured to monitor a status of the sealant nozzle 106, a status of the gas purger 108, and a status of the stack of wafers 104 on the wafer stage 102 based on captured images. In some embodiments, the imager 110 is configured to monitor the sealant particle buildup on the sealant nozzle 106. In some embodiments, the imager 110 is configured to monitor the sealant particle buildup on the gas purger 108. In some embodiments, the imager 110 is configured to monitor the sealing layer 120 formed on the side surface 104c of the stack of wafers 104.

In some embodiments, the sealing apparatus 100 further includes a nozzle cleaner 112. The nozzle cleaner 112 is configured to clean the sealant nozzle 106 by removing sealant particle buildup within and around the sealant nozzle 106.

In some embodiments, the nozzle cleaner 112 is arranged near the sealant nozzle 106. In some embodiments, the nozzle cleaner 112 is configured to automatically clean the sealant nozzle 106 upon detection of sealant particle buildup within and around the sealant nozzle 106. In some embodiments, the nozzle cleaner 112 is configured to periodically clean the sealant nozzle 106.

In some embodiments, the nozzle cleaner 112 is arranged near the gas purger 108. In some embodiments, the nozzle cleaner 112 is configured to automatically clean the plurality of holes of the gas purger 108 upon detection of sealant particle buildup within and around the plurality of holes of the gas purger 108. In some embodiments, the nozzle cleaner 112 is configured to periodically clean the plurality of holes of the gas purger 108.

In some embodiments, the sealing apparatus 100 further includes a microbalance sensor 114 connected and/or coupled with the wafer stage 102. In some embodiments, the microbalance sensor 114 is configured to monitor and/or detect a status of the stack of wafers 104 on the wafer stage 102. In some embodiments, the microbalance sensor 114 is configured to detect a mass change of the stack of wafers 104. In some examples, the microbalance sensor 114 is configured to monitor the balance of the stack of wafers, such that uniformity of the sealant layer formed on the side surface 104c of the stack of the wafers 104 can be determined.

In some embodiments, the microbalance sensor 114 is configured to continuously monitor and/or detect the status of the stack of wafers 104 on the wafer stage 102. In some embodiments, the microbalance sensor 114 is configured to periodically monitor and/or detect the status of the stack of wafers 104 on the wafer stage 102.

In some embodiments, as shown in FIG. 1, the sealing apparatus 100 further includes a housing 101 including a vacuum chamber 101a for sealing the stack of wafers 104. In some embodiments, the housing 101 is connected to a vacuum pump that evacuates vacuum chamber to provide a vacuum in the vacuum chamber.

In some embodiments, the wafer stage 102, the sealant nozzle 106, the gas purger 108, the imager 110, the nozzle cleaner 112, and the microbalance sensor 114, are positioned within the housing 101 and perform a sealing process on the stack of wafers 104 in the vacuum chamber 101a. In some embodiments, the sealing process within the vacuum chamber 101a reduces contaminant particle buildup on the wafer stage 102, the sealant nozzle 106, the gas purger 108, the imager 110, the nozzle cleaner 112, and the microbalance sensor 114. In some embodiments, the housing 101 is frequently and/or periodically maintained to prevent contaminant particle buildup on the inside walls of the housing 101.

In some embodiments, the sealing apparatus 100 further includes a controller 150 electrically or wirelessly connected to and/or coupled with the wafer stage 102, sealant nozzle 106, the gas purger 108, the imager 110, and the microbalance sensor 114. The controller 150 is configured to receive and process the generated data from the wafer stage 102, the sealant nozzle 106, the gas purger 108, the imager 110, and the microbalance sensor 114. In some embodiments, the controller 250 is a microcontroller configured to receive and process the generated data and adjust setting parameters of the wafer stage 102, the sealant nozzle 106, the gas purger 108, the imager 110, and the microbalance sensor 114 based on the generated data.

In some examples, the controller 150 is electrically or wirelessly connected to and/or coupled with the pump for the sealant nozzle 106. The controller 150 is configured to control and/or adjust the flow rate of the sealant flow 106a.

In some examples, the controller 150 includes software and hardware for image storage, image comparison, and image evaluation. In one example, the controller 150 includes a media, such as flash memory device or hard disk, to save the images of the sealant nozzle 106, the gas purger 108, and the stack of wafers on the wafer stage 102. In another embodiment, the controller 150 includes an algorithm that processes a plurality of images associated with the sealant nozzle 106, the gas purger 108, and the stack of wafers 104 on the wafer stage 102, to determine the status of the sealant nozzle 106, the status of the gas purger 108, and the status of the stack of wafers 104 on the wafer stage 102.

It is understood that the controller 150 may be concentrated at a single location or distributed. In one embodiment, the controller 150 is embedded in the sealing apparatus 100. In one embodiment, as shown in FIG. 1, the controller 150 is positioned outside of the housing 101. In another embodiment, the controller 150 is remotely connected to the sealing apparatus 100 through the internet, intranet, or other data communication mechanisms. In yet another embodiment, the controller 150 is a portion of a semiconductor device manufacturing system and is coupled to the sealing apparatus 100 through a suitable data communication mechanism.

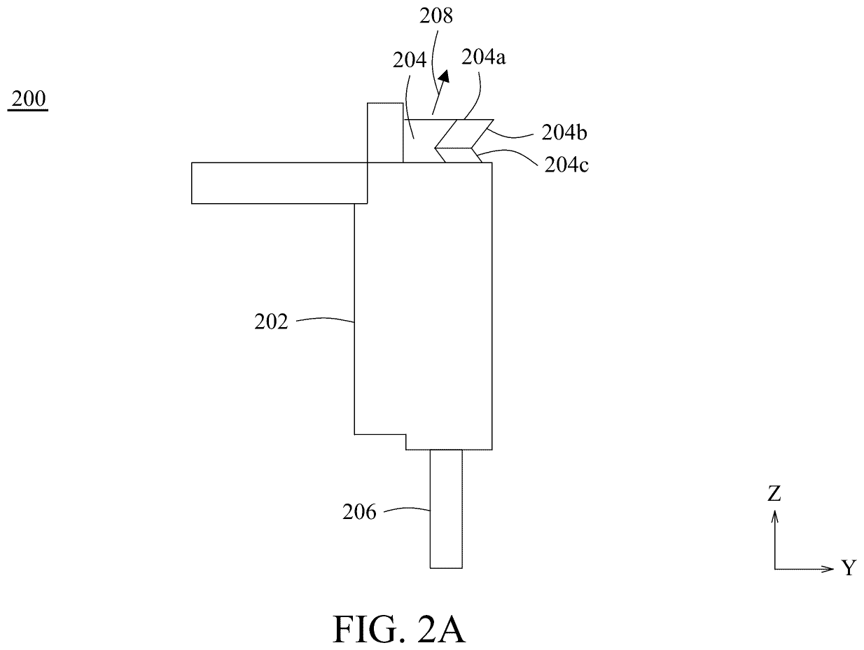

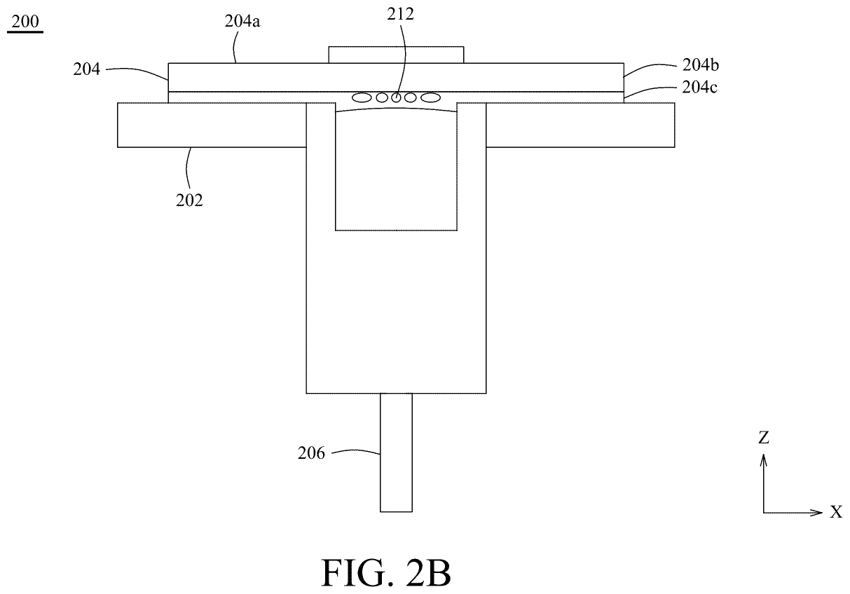

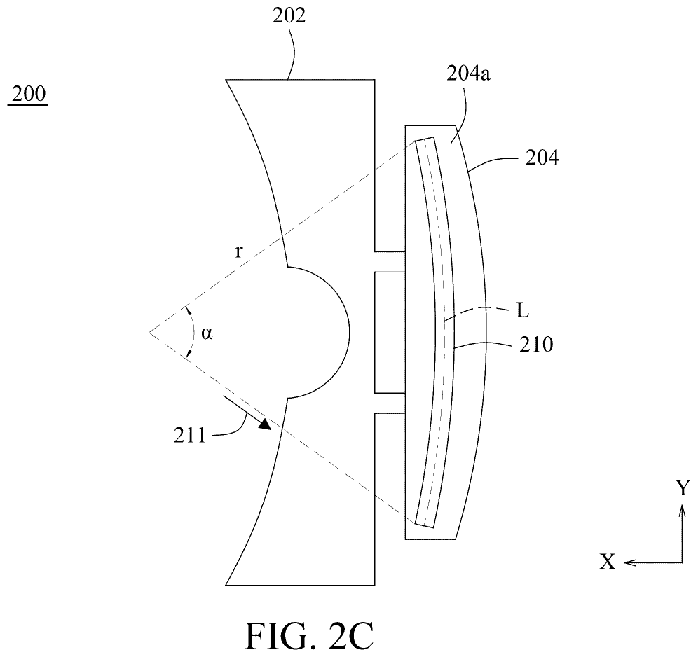

FIG. 2A is a front view of a gas purger 200 in accordance with some embodiments of the present disclosure. FIG. 2B is a side view of the gas purger 200 in accordance with some embodiments of the present disclosure. FIG. 2C is a top view of the gas purger 200 in accordance with some embodiments of the present disclosure. Components of the gas purger 200 described herein correspond to the components of the gas purger 108 as described in FIG. 1.

In some embodiments, as shown in FIG. 2A, FIG. 2B, and FIG. 2C, the gas purger 200 includes a base portion 202 and a head portion 204. In some embodiments, the base portion 202 is a supporting base and configured to engage with the head portion 204, such that the head portion 204 can be arranged adjacent to the backside surface 104b of the stack of wafers 104 and the side surface 104c of the stack of wafers 104, as shown in FIG. 1.

In some embodiments, the base portion 202 is configured to be attached to the wafer stage 102, such that the gas purger 200 can be attached to the wafer stage.

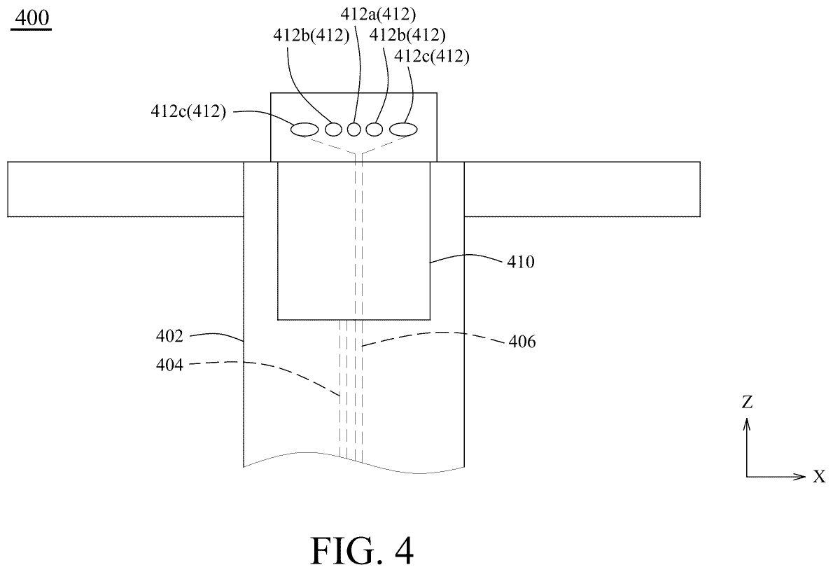

In some embodiments, the base portion 202 includes gas flow paths (see FIG. 4) for supplying the purge gas to the head portion 204 and removing the purge gas from the head portion.

In some embodiments, as shown in FIG. 2B and FIG. 2C, the head portion 204 includes a gas diffusion channel 210 arranged at a top surface 204a of the head portion 204. The gas diffusion channel directs the purge gas to distribute toward the backside surface 104b of the stack of wafers 104.

In some embodiments, the gas diffusion channel 210 is a curved channel. In some embodiments, the gas diffusion channel 210 is an arc-shaped channel. In some embodiments, the gas diffusion channel 210 is formed by sidewalls of the head portion 204. In some embodiments, the sidewalls of the head portion 204 include three vertical sidewalls and a non-vertical sidewall to form a path channel for the purge gas. The vertical sidewalls are perpendicular to the backside surface 104b of the stack of wafers 104. In some embodiments, the non-vertical sidewall is arranged at a side of the head portion 204, which is closer to the sealant nozzle 106 than the three vertical sidewalls. In some embodiments, the non-vertical sidewall includes a top portion 204b and a bottom portion 204c. The top portion 204b and the bottom portion 204c meet and form an inward-facing angle. The top portion 204b and the three vertical sidewalls are configured to guide a purge gas flow 208 from the gas diffusion channel 210. In some embodiments, the purge gas flow 208 is directed at an acute angle relative to the backside surface 104b of the stack of wafers 104 and tilted toward the sealant nozzle 106.

In some embodiments, as shown in FIG. 2C, the arc-shaped channel has a central angle α subtended by the arc of the arc-shaped channel. In some embodiments, the central angle α is in a range from about 5° to about 60°. In some embodiments, the central angle α is in a range from about 10° to about 45°. In some embodiments, the central angle α is in a range from about 25° to about 35°. If the central angle α is less than 5°, then there may not be sufficient vacuum to remove all the contaminants. If the central angle α is greater than 60°, then the vacuum may become inefficient.

In some embodiments, the arc-shaped channel has a length L in a range from about 10 mm to about 150 mm. In some embodiments, the arc-shaped channel has a length L in a range from about 50 mm to about 90 mm. In some embodiments, the arc-shaped channel has a length L in a range from about 65 mm to about 75 mm. If the length L is less than 10 mm, then there may not be sufficient vacuum to remove all the contaminants. If the length L is greater than 150 mm, then the vacuum may become inefficient.

In some embodiments, the arc-shaped channel has a radius r. In some embodiments, the radius of the arc-shaped channel is equal to a radius of the stack of wafers 104.

In some embodiments, as shown in FIG. 2B, the head portion 204 further includes a plurality of vacuum holes 212 arranged at the non-vertical sidewall (204b and 204c) of the head portion 204. In some embodiments, the plurality of vacuum holes 212 are arranged at the bottom portion 204c of the non-vertical sidewall (204b and 204c) of the head portion 204.

In some embodiments, the plurality of vacuum holes 212 are configured to remove the sealant particles that are not deposited and exhaust the purge gas from the sealing apparatus 100.

In some embodiments, the gas purger 200 includes a plurality of pipelines 206. In some embodiments, the plurality of pipelines 206 include a purge gas pump line and an exhaust vacuum line. In some embodiments, the purge gas pump line is configured to couple and/or connect the head portion 204 with an external gas tank (not shown) for supplying the purge gas to the sealing apparatus. In some embodiments, the exhaust vacuum line is configured to couple and/or connect the head portion 204 with a vacuum pump (not shown) for removing the purge gas and the sealant particles from the sealing apparatus.

In some embodiments, the gas flow paths of the base portion 202 include a first gas flow path coupling and/or connecting the gas diffusion channel 210 with the external gas tank for supplying the purge gas to the sealing apparatus 100. In some embodiments, the gas flow paths of the base portion 202 include a second gas flow path coupling and/or connecting the plurality of vacuum holes 212 with the vacuum pump for removing and/or exhausting the purge gas from the sealing apparatus 100.

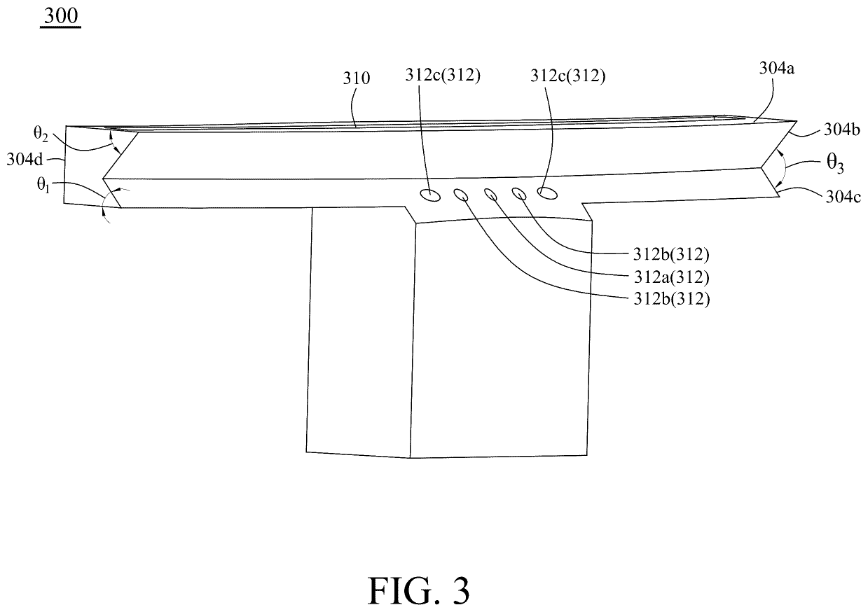

FIG. 3 is a perspective view of a head portion 300 of a gas purger in accordance with some embodiments of the present disclosure. Components of the head portion 300 described herein correspond to the components of the head portion 204 as described in FIG. 2A, FIG. 2B, and FIG. 2C.

In some embodiments, as shown in FIG. 3, the head portion 300 includes a gas diffusion channel 310 arranged at a top surface 304a of the head portion 300.

In some embodiments, the gas diffusion channel 310 is a curved channel. In some embodiments, the gas diffusion channel 310 is an arc-shaped channel. In some embodiments, the gas diffusion channel 310 is formed by sidewalls of the head portion 300. In some embodiments, the sidewalls of the head portion 300 include three vertical sidewalls 304d and a non-vertical sidewall (304b and 304c). In some embodiments, the non-vertical sidewall is arranged closer to the sealant nozzle 106 than the three vertical sidewalls 304d. In some embodiments, the non-vertical sidewall includes a top portion 304b and a bottom portion 304c. The top portion 304b and the bottom portion 304c meet and form an inward-facing angle θ₃.

In some embodiments, as shown in FIG. 3, the head portion 300 further includes a plurality of vacuum holes 312 arranged at the non-vertical sidewall (304b and 304c) of the head portion 300. In some embodiments, the plurality of vacuum holes 312 are arranged at the bottom portion 304c of the non-vertical sidewall (304b and 304c) of the head portion 300. In some embodiments, the plurality of vacuum holes 312 are configured to remove and/or exhaust the purge gas from the sealing apparatus 100.

In some embodiments, the plurality of vacuum holes 312 are aligned and uniformly distributed on the bottom portion 304c of the non-vertical sidewall (304b and 304c).

In some embodiments, the plurality of vacuum holes 312 are equally spaced from each other.

In some embodiments, the plurality of vacuum holes 312 include a first vacuum hole 312a arranged at a center of the bottom portion 304c of the non-vertical sidewall (304b and 304c). In some embodiments, the first vacuum hole has a first area A₁.

In some embodiments, the plurality of vacuum holes 312 further include two second vacuum holes 312b arranged at two sides of the first vacuum hole 312a, respectfully. In some embodiments, each of the two second vacuum holes has a second area A₂. In some embodiments, A₂ is greater than A₁ and less than 2×A₁. If the second area A₂ is smaller than the first area A₁, then the two second vacuum holes 312b may not be able to provide a sufficient vacuum pressure to remove contaminants away from the center of the bottom portion 304c of the non-vertical sidewall. If the second area A₂ is greater than 2×A₁, then the two second vacuum holes 312b may produce too much localized airflow disturbance.

In some embodiments, the plurality of vacuum holes 312 further include two third vacuum holes 312c arranged at a side of each of the two second vacuum holes 312b away from the first vacuum hole 312a. In some embodiments, each of the two third vacuum holes has a third area A₃. In some embodiments, A₃ is greater than 2×A₁ and less than 3×A₁. If the third area A₃ is smaller than 2×A₁, then the two third vacuum holes 312c may not be able to provide a sufficient vacuum pressure to remove contaminants at the edges of the bottom portion 304c of the non-vertical sidewall. If the third area A₃ is greater than 3×A₁, then the two third vacuum holes 312c may produce too much localized airflow disturbance.

In some embodiments, a total area of the plurality of vacuum holes 312 is in a range from about 5 mm² to about 80 mm². In some embodiments, the total area of the plurality of vacuum holes 312 is in a range from about 10 mm² to about 40 mm². In some embodiments, the total area of the plurality of vacuum holes 312 is in a range from about 20 mm² to about 30 mm². If the total area of the plurality of vacuum holes is less than 5 mm², then there may not be sufficient vacuum to remove all the contaminants. If the total area of the plurality of vacuum holes is greater than 80 mm², then the vacuum may negatively affect the formation of the sealing layer on the side surface of the stack of wafers.

Although five vacuum holes 312 are shown in FIG. 3, any suitable number of vacuum holes can be included in the head portion 300. In some embodiments, there are fewer than five vacuum holes 312 or more than five vacuum holes in the head portion 300.

In some embodiments, the area of the vacuum hole increases as a distance between the vacuum hole and the first vacuum hole 312a increases.

In some embodiments, as shown in FIG. 3, the bottom portion 304c of the non-vertical sidewall (304b and 304c) of the head portion 300 has an angle θ₁ relative to a plane parallel to the top surface of the wafer platform 102a. In some embodiments, referring back to FIG. 1, the top surface of the wafer platform 102a is flush with the backside surface 104b of the stack of the wafers 104. In some embodiments, the angle θ₁ is an acute angle such that the efficiency of removing the purge gas and/or the sealant particles from the sealing apparatus can be improved. In some embodiments, the angle θ₁ is in a range from about 10° to about 85°. In some embodiments, the angle θ₁ is in a range from about 30° to about 80°. In some embodiments, the angle θ₁ is in a range from about 40° to about 65°. If the angle θ₁ is less than 10° or greater than 85°, then the vacuum may become inefficient to remove all the contaminants.

In some embodiments, as shown in FIG. 3, the top portion 304b of the non-vertical sidewall (304b and 304c) of the head portion 300 has an angle θ₂ relative to a plane parallel to the top surface of wafer platform 102a. In some embodiments, the angle θ₂ is an acute angle, such that the purge gas flow is guided from the gas diffusion channel 210. In some embodiments, the purge gas flow is directed at an acute angle relative to the bottom surface of the stack of wafers and tilted toward the sealant nozzle. In some embodiments, the angle θ₂ is in a range from about 10° to about 85°. In some embodiments, the angle θ₂ is in a range from about 30° to about 80°. In some embodiments, the angle θ₂ is in a range from about 40° to about 65°. In some embodiments, the angle θ₁ is equal to the angle θ₂. If the angle θ₂ is less than 10° or greater than 85°, then the purge gas flow may become inefficient to remove all the contaminants.

FIG. 4 is a side view of a base portion 400 of a gas purger, in accordance with some embodiments of the present disclosure. Components of the base portion 400 described herein correspond to the components of the base portion 202 as described in FIG. 2A, FIG. 2B, and FIG. 2C.

In some embodiments, as shown in FIG. 4, the base portion 400 of the gas purger includes a first gas flow path 404 for supplying the purge gas to the head portion 204 and a second gas flow path 406 for removing the purge gas and the sealant particles from the sealing apparatus 100 through the head portion.

In some embodiments, the first gas flow path 404 is configured to couple and/or connect the gas diffusion channel 210 with a first pipeline of the plurality of pipelines 206 for supplying the purge gas to the sealing apparatus 100. In some embodiments, the second gas flow path 406 is configured to couple and/or connect the plurality of vacuum holes 212 with a second pipeline of the plurality of pipelines 206 for removing and/or exhausting the purge gas and the sealant particles from the sealing apparatus 100.

In some embodiments, the first pipeline is coupled with and/or connected to a gas tank (not shown) for supplying the purge gas. In some embodiments, the second pipeline is coupled with and/or connected to a vacuum pump (not shown) for removing and/or exhausting the purge gas and the sealant particles.

In some embodiments, the base portion 400 of the gas purger includes a groove 410 configured to engage the base portion 400 with the head portion 204 by inserting a portion of the head portion 204 into the groove 410.

In some embodiments, the second gas flow path 406 includes a plurality of inlet ports 412. In some embodiments, after the base portion 400 is engaged with the head portion (e.g., 300 of FIG. 3), each of the plurality of inlet ports 412 is arranged to couple and/or match with a corresponding vacuum hole of the plurality of vacuum holes 312, such that the purge gas and the sealant particles can be removed and/or exhausted from the sealing apparatus 100.

In some embodiments, the plurality of inlet ports 412 are uniformly distributed on a center portion of the base portion 402.

In some embodiments, the plurality of inlet ports 412 are equally spaced from each other.

In some embodiments, the plurality of inlet ports 412 include a first inlet port 412a arranged to engage and match with the first vacuum hole 312a. The first inlet port has a fourth area B₁. In some embodiments, B₁=A₁.

In some embodiments, the plurality of inlet ports 412 include two second inlet ports 412b arranged at two sides of the first inlet port 412a and configured to engage and match with the two second vacuum holes 312b, respectfully. Each of the two second inlet ports has a fifth area B₂. In some embodiments, B₂ is greater than B₁ and less than 2×B₁. In some embodiments, B₂=A₂.

In some embodiments, the plurality of inlet ports 412 include two third inlet ports 412c arranged at a side of each of the two second inlet ports 412b away from the first inlet port 412a. The two third inlet ports are configured to engage and match with the two third vacuum holes 312c, respectfully. Each of the two third inlet ports has a sixth area B₃. In some embodiments, B₃ is greater than 2×B₁ and less than 3×B₁. In some embodiments, B₃=A₃.

Although five inlet ports 412 are shown in FIG. 3, any suitable number of inlet ports can be included in the base portion 400 to match with the number of vacuum holes 312 in the head portion 300. In some embodiments, there are fewer than five inlet ports 412 or more than five inlet ports in the base portion 400.

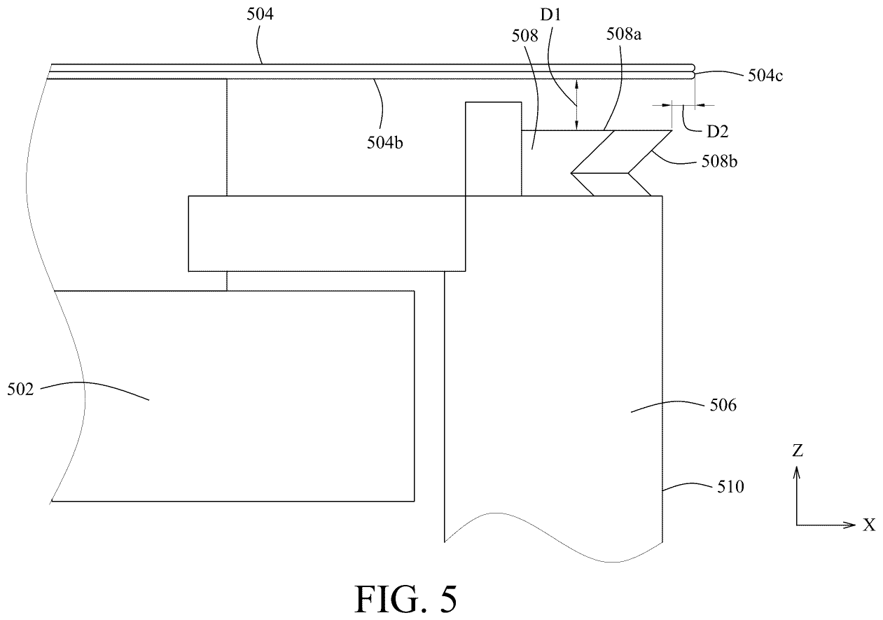

FIG. 5 is a close-up view of a portion of a sealing apparatus 500 in accordance with some embodiments of the present disclosure. Components of the sealing apparatus 500 described herein correspond to the components of the sealing apparatus 100 as described in FIG. 1.

In some embodiments, as shown in FIG. 5, the sealing apparatus 500 includes a wafer stage 502. In some embodiments, the wafer stage 502 is configured to hold a stack of wafers 504 on a wafer platform of the wafer stage 502. In some embodiments, the stack of wafers 504 has a backside surface 504b and a side surface 504c.

In some embodiments, as shown in FIG. 5, the sealing apparatus 500 further includes a gas purger 506 arranged on the side of the wafer stage 502. In some embodiments, the gas purger 506 includes a head portion 508 and a base portion 510.

In some embodiments, the base portion 510 is a supporting base and configured to engage with the head portion 508, such that the head portion 508 can be arranged adjacent to a backside surface 504b of the stack of wafers 504 and a side surface 504c of the stack of wafers 504.

In some embodiments, the base portion 510 is configured to be attached to the wafer stage 502, such that the gas purger 506 can be attached to the wafer stage 502.

In some embodiments, a top surface 508a of the head portion 508 is spaced away from the backside surface 504b of the stack of wafers 504, such that the sealant particles from the sealant flow are not pushed toward the backside surface 504b of the stack of wafers 504. Additionally, the space between the backside surface 504b of the stack of wafers 504 and the top surface 508a of the head portion 508 is controlled, such that a pressure higher than an ambient pressure is maintained at the backside surface 504b of the stack of wafers 504 to further prevent the sealant particles from the sealant flow to be deposited on the backside surface 504b of the stack of wafers 504.

In some embodiments, a distance D₁ between the backside surface 504b of the stack of wafers 504 and the top surface 508a of the head portion 508 is in a range from about 0.5 mm to about 20 mm. In some embodiments, the distance D₁ between the backside surface 504b of the stack of wafers 504 and the top surface 508a of the head portion 508 is in a range from about 1 mm to about 10 mm. In some embodiments, the distance D₁ between the backside surface 504b of the stack of wafers 504 and the top surface 508a of the head portion 508 is in a range from about 3 mm to about 7 mm. If the distance D₁ between the backside surface 504b of the stack of wafers 504 and the top surface 508a of the head portion 508 is less than 0.5 mm, then the sealant flow may be pushed toward the backside surface 504b of the stack of wafers 504. If the distance D₁ between the backside surface 504b of the stack of wafers 504 and the top surface 508a of the head portion 508 is greater than 20 mm, then the pressure at the backside surface 504b of the stack of wafers 504 may not be maintained higher than the ambient pressure.

In some embodiments, the head portion 508 is recessed away from the side surface 504c of the stack of wafers 504, such that the sealant particles from the sealant flow are pushed away from the backside surface 504b of the stack of wafers 504. In some embodiments, a distance D₂ between the side surface 504c of the stack of wafers 504 and an edge 508b of the head portion 508 in the horizontal direction (e.g. a radial direction 211 of the gas diffusion channel 210 as shown in FIG. 2C) is in a range from about 0.5 mm to about 20 mm. In some embodiments, the distance D₂ between the side surface 504c of the stack of wafers 504 and the edge 508b of the head portion 508 in the horizontal direction is in a range from about 1 mm to about 10 mm. In some embodiments, the distance D₂ between the side surface 504c of the stack of wafers 504 and the edge 508b of the head portion 508 in the horizontal direction is in a range from about 3 mm to about 7 mm. If the distance D₂ between the side surface 504c of the stack of wafers 504 and an edge 508b of the head portion 508 is less than 1 mm or greater than 10 mm, then the contaminants may not be removed efficiently.

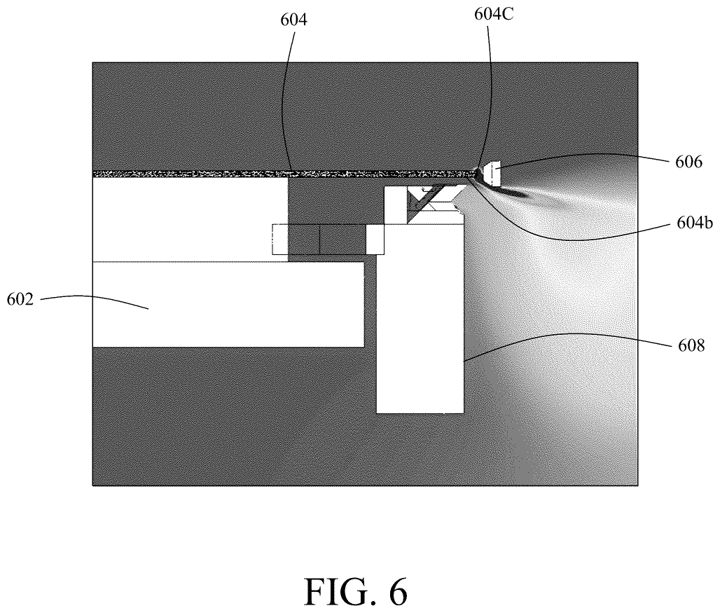

FIG. 6 is a flow field concentration distribution map 600 in accordance with some embodiments of the present disclosure.

In some embodiments, as shown in FIG. 6, the flow field concentration distribution map 600 demonstrates a sealant particle concentration distribution around a wafer stage 602, a stack of wafers 604, a sealant nozzle 606, and a gas purger 608. The wafer stage 602, the stack of wafers 604, the sealant nozzle 606, and the gas purger 608 described herein correspond to the wafer stage 102, the stack of wafers 104, the sealant nozzle 106, and the gas purger 108 as described in FIG. 1.

As shown in FIG. 6, the concentration of the sealant particles is the greatest at the side surface 604c of the stack of wafers 604. In addition, the concentration of the sealant particles is smallest at the backside surface 604b of the stack of wafers 604.

In some embodiments, the concentration of the sealant particles at the backside surface 604b of the stack of wafers 604 is decreased by a factor of 1000 to 10000 in comparison to a sealing apparatus without the gas purger. The gas purger blows the sealant particles away from the backside surface of the stack of wafers, thereby reducing the sealant particle contamination on the backside surface of the stack of wafers.

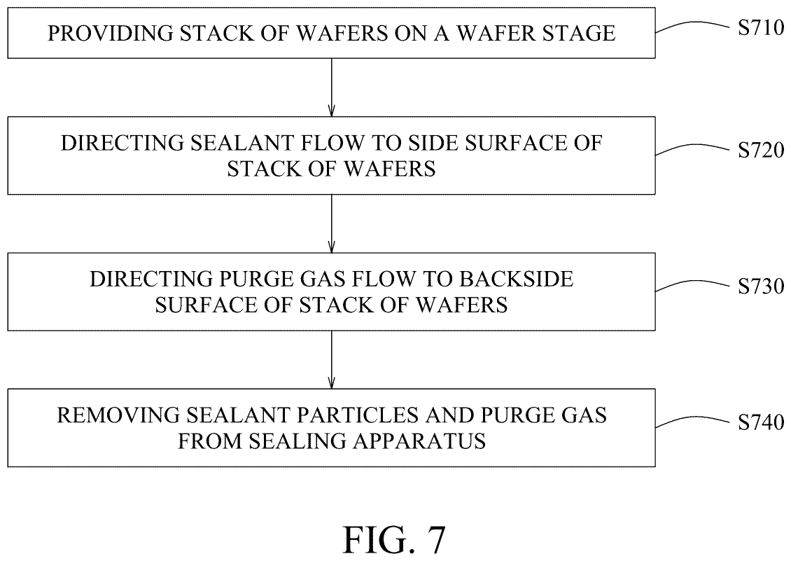

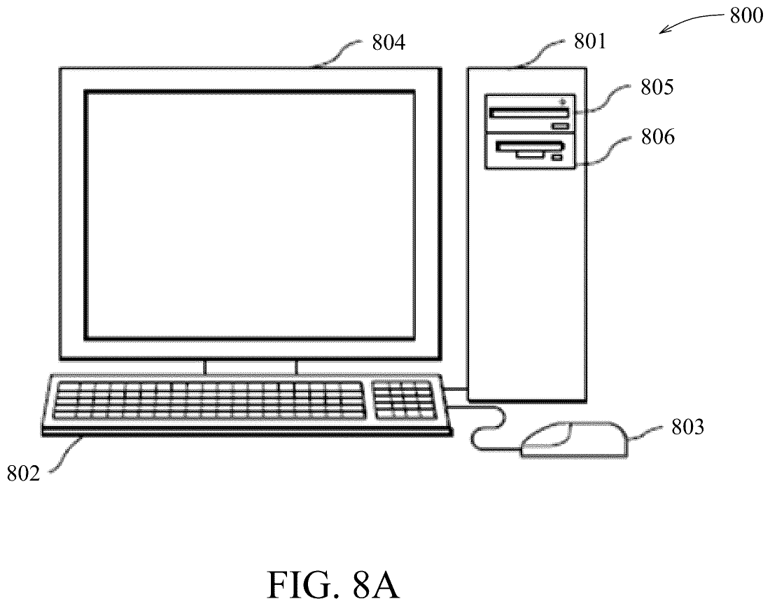

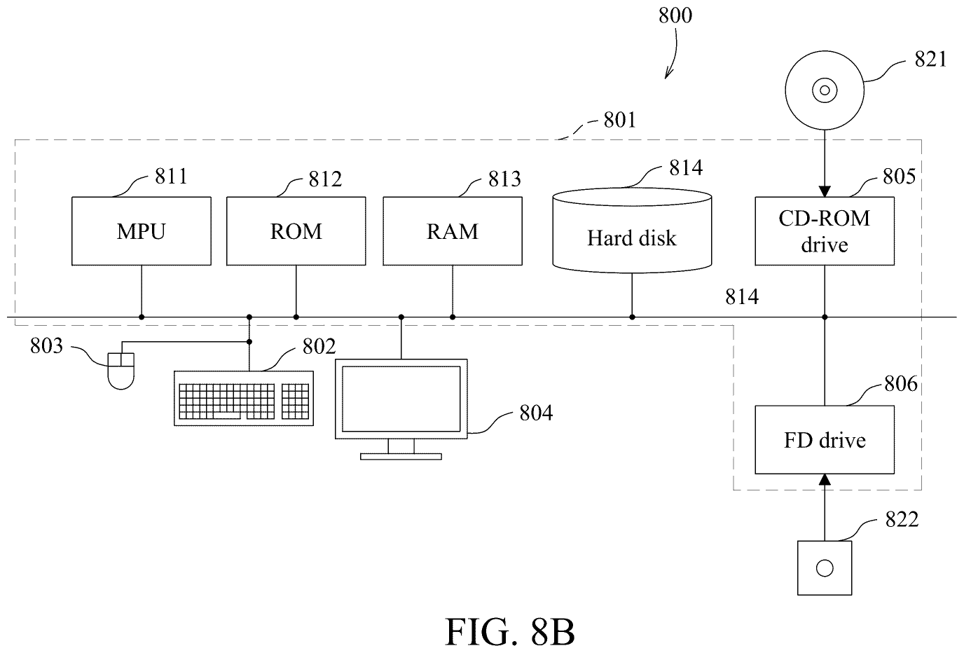

FIG. 7 illustrates a flow diagram of a method 700 for manufacturing a semiconductor device in accordance with some embodiments of the present disclosure. The method 700 or a portion of the method 700 is performed by a controller (e.g., 150 of FIG. 1). In some embodiments, the method 700 or a portion of the method 700 is performed and/or is controlled by a computer system 800 described below with respect to FIGS. 8A and 8B. The method 700 is an example, and is not intended to limit the present disclosure and what is claimed. Additional operations can be provided before, during, and after the method 700, and some operations described can be replaced, eliminated, or moved around for additional embodiments of the method 700.

In some embodiments, the method 700 includes an operation S710 as shown in FIG. 7. In operation S710, a stack of wafers 104 is provided on a wafer stage 102 as shown in FIG. 1.

In some embodiments, the wafer stage 102 includes a wafer platform 102a, which is configured to hold the stack of wafers 104 on the wafer platform 102a.

In some embodiments, the method further includes an operation S720 as shown in FIG. 7. In operation S720, as shown in FIG. 1, a sealant flow 106a is directed to the side surface 104c of the stack of wafers 104.

In some embodiments, as shown in FIG. 1, a sealing layer 120 is formed on the side surface 104c of the stack of wafers 104 after sealant particles from the sealant flow 106a are deposited on the side surface 104c of the stack of wafers 104. In some embodiments, the sealing layer 120 seals the bevel edge of the stack of wafers 104 to protect the bevel edge of the stack of wafers 104 from edge chipping.

In some embodiments, the method further includes an operation S730 as shown in FIG. 7. In operation S730, as shown in FIG. 2A, a purge gas flow 208 is directed to the backside surface 104b of the stack of wafers 104.

In some embodiments, the purge gas flow 208 is directed at an acute angle relative to the backside surface 104b of the stack of wafers 104 and is tilted toward the sealant nozzle 106.

In some embodiments, as shown in FIG. 2A, FIG. 2B, and FIG. 2C, the purge gas flow 208 is guided by the gas diffusion channel 210 of the head portion 204 of the gas purger 200.

In some embodiments, the gas purger 200 is attached to the wafer stage 102 and the head portion 204 is engaged with the base portion 202 to provide the purge gas flow 208. In some embodiments, the method further includes flowing the purge gas through the base portion toward the head portion.

In some embodiments, the gas diffusion channel 210 is arranged at a top surface 204a of the head portion 204. In some embodiments, the method further includes flowing the purge gas through the gas diffusion channel 210 toward the backside surface 104b of the stack of wafers 104.

In some embodiments, a plurality of vacuum holes 212 are arranged at a non-vertical sidewall of the head portion. In some embodiments, the method further includes removing the sealant particles and the purge gas through the plurality of vacuum holes.

In some embodiments, the operations S730 and S720 are performed simultaneously.

In some embodiments, the method further includes an operation S740 as shown in FIG. 7. In operation S740, as shown in FIG. 1, sealant particles and the purge gas are removed from the sealing apparatus 100.

In some embodiments, the sealant particles that are not deposited are removed through the plurality of holes on the head portion 204 of the gas purger 200. In some embodiments, the purge gas is also removed from the sealing apparatus 100.

In some embodiments, the operations S740 and S730 are performed simultaneously.

FIGS. 8A and 8B illustrate a computer system 800 for implementing various methods described herein in accordance with some embodiments of the present disclosure. In some embodiments, the computer system 800 is used for performing the functions of the controller 150 of FIG. 1, and/or operations of method 700 of FIG. 7.

FIG. 8A is a schematic view of a computer system that performs the functions of a sealing apparatus. All of or a part of the processes, methods, and/or operations of the foregoing embodiments can be realized using computer hardware and computer programs executed thereon. In FIG. 8A, a computer system 800 is provided with a computer 801 including an optical disk read only memory (e.g., CD-ROM or DVD-ROM) drive 805 and a magnetic disk drive 806, a keyboard 802, a mouse 803, and a monitor 804.

FIG. 8B is a diagram showing an internal configuration of the computer system 800. In FIG. 8B, the computer 801 is provided with, in addition to the optical disk drive 805 and the magnetic disk drive 806, one or more processors, such as a micro processing unit (MPU) 811, a read only memory (ROM) 812 in which a program such as a boot up program is stored, a random access memory (RAM) 813 that is connected to the MPU 811 and in which a command of an application program is temporarily stored and a temporary storage area is provided, a hard disk 814 in which an application program, a system program, and data are stored, and a bus 815 that connects the MPU 811, the ROM 812, and the like. Note that the computer 801 may include a network card (not shown) for providing a connection to a LAN.

The program for causing the computer system 800 to execute the functions for the sealing apparatus in the foregoing embodiments may be stored in an optical disk 821 or a magnetic disk 822, which are inserted into the optical disk drive 805 or the magnetic disk drive 806, and transmitted to the hard disk 814. Alternatively, the program may be transmitted via a network (not shown) to the computer 801 and stored in the hard disk 814. At the time of execution, the program is loaded into the RAM 813. The program may be loaded from the optical disk 821 or the magnetic disk 822, or directly from a network. The program does not necessarily have to include, for example, an operating system (OS) or a third-party program to cause the computer 801 to execute the functions of the control system for removing contaminant particles on the patterning mask of the lithography system in the foregoing embodiments. The program may only include a command portion to call an appropriate function (module) in a controlled mode and obtain desired results.

The novel apparatuses and the methods according to the present disclosure provide an improved apparatus and methods for manufacturing the semiconductor device, thereby reducing the sealant particle contamination on the backside surface of the stack of wafers. Embodiments of the disclosure provide apparatuses and methods using a gas purge module to prevent the polymer sealant particles from depositing on the backside surface of the wafers, thereby reducing the contamination on the wafer edges. Consequently, the defect rate of wafer products can be reduced, and the quality of the wafer product can be improved.

According to some embodiments of the present disclosure, a sealing apparatus is provided. The sealing apparatus includes a wafer stage configured to hold a stack of wafers on the wafer stage and a nozzle arranged at a side of the wafer stage and configured to direct a sealant flow to a side surface of the stack of wafers. The sealing apparatus further includes a gas purger arranged at the side of the wafer stage and configured to direct a purge gas flow toward a backside surface of the stack of wafers. In an embodiment, the gas purger includes a base portion configured to attach the gas purger to the wafer stage, and a head portion configured to engage with the base portion and direct the purge gas flow toward the backside surface of the stack of wafers. In an embodiment, the head portion includes a gas diffusion channel arranged at a top surface of the head portion and configured to direct the purge gas flow toward the backside surface of the stack of wafers, and a plurality of vacuum holes arranged at a non-vertical sidewall of the head portion and configured to remove sealant particles and purge gas from the sealing apparatus. In an embodiment, the gas diffusion channel is an arc-shaped channel. A length of the gas diffusion channel is in a range from 50 mm to 90 mm. A central angle of the gas diffusion channel is in a range from 10° to 45°. In an embodiment, the gas diffusion channel is formed by three vertical sidewalls and the non-vertical sidewall of the head portion, and the non-vertical sidewall includes a top portion and a bottom portion forming an inward-facing angle. In an embodiment, the plurality of vacuum holes are arranged at the bottom portion of the non-vertical sidewall. In an embodiment, the plurality of vacuum holes include a first vacuum hole arranged at a center of the bottom portion of the non-vertical sidewall, where the first vacuum hole has a first area A₁, and two second vacuum holes arranged at two sides of the first vacuum hole. Each of the two second vacuum holes has a second area A₂, and A₂ is greater than A₁ and less than 2×A₁. In an embodiment, the plurality of vacuum holes further include two third vacuum holes arranged at a side of each of the two second vacuum holes away from the first vacuum hole. Each of the two third vacuum holes has a third area A₃, and A₃ is greater than 2×A₁ and less than 3×A₁. In an embodiment, the plurality of vacuum holes are uniformly distributed on the non-vertical sidewall of the head portion. In an embodiment, a total area of the plurality of vacuum holes is in a range from 10 mm² to 40 mm². In an embodiment, a distance between the backside surface of the stack of wafers and the top surface of the head portion is in a range from 1 mm to 10 mm, and a distance between the side surface of the stack of wafers and an edge of the head portion in a horizontal direction is in a range from 1 mm to 10 mm.

According to some embodiments of the present disclosure, a gas purge device for a sealing apparatus is provided. The gas purge device includes a base portion configured to attach the gas purge device to a wafer stage of the sealing apparatus; and a head portion configured to engage with the base portion. The head portion includes a gas diffusion channel arranged at a top surface of the head portion and configured to direct a purge gas flow toward a backside surface of a stack of wafers, and a plurality of vacuum holes arranged at a non-vertical sidewall of the head portion and configured to remove sealant particles and purge gas from the sealing apparatus.

According to some embodiments of the present disclosure, a method for manufacturing a semiconductor device is provided. The method includes providing a stack of wafers on a wafer stage of a sealing apparatus, and directing, by a nozzle arranged at a side of the wafer stage, a sealant flow to a side surface of the stack of wafers. The method further includes directing, by a gas purger arranged at the side of the wafer stage, a purge gas flow to a backside surface of the stack of wafers, and removing sealant particles and purge gas from the sealing apparatus.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A sealing apparatus, comprising:
a wafer stage configured to hold a stack of wafers on the wafer stage;
a nozzle arranged at a side of the wafer stage and configured to direct a sealant flow to a side surface of the stack of wafers; and
a gas purger arranged at the side of the wafer stage and configured to direct a purge gas flow toward a backside surface of the stack of wafers.

2. The sealing apparatus of claim 1, wherein the gas purger includes:
a base portion configured to attach the gas purger to the wafer stage; and
a head portion configured to engage with the base portion and direct the purge gas flow toward the backside surface of the stack of wafers.

3. The sealing apparatus of claim 2, wherein the head portion includes:
a gas diffusion channel arranged at a top surface of the head portion and configured to direct the purge gas flow toward the backside surface of the stack of wafers; and
a plurality of vacuum holes arranged at a non-vertical sidewall of the head portion and configured to remove sealant particles and purge gas from the sealing apparatus.

4. The sealing apparatus of claim 3, wherein the gas diffusion channel is an arc-shaped channel, where:
a length of the gas diffusion channel is in a range from 50 mm to 90 mm, and
a central angle of the gas diffusion channel is in a range from 10° to 45°.

5. The sealing apparatus of claim 3, wherein:
the gas diffusion channel is formed by three vertical sidewalls and the non-vertical sidewall of the head portion, and
the non-vertical sidewall includes a top portion and a bottom portion forming an inward-facing angle.

6. The sealing apparatus of claim 5, wherein:
the plurality of vacuum holes are arranged at the bottom portion of the non-vertical sidewall.

7. The sealing apparatus of claim 5, wherein the plurality of vacuum holes include:
a first vacuum hole arranged at a center of the bottom portion of the non-vertical sidewall, wherein the first vacuum hole has a first area A₁; and
two second vacuum holes arranged at two sides of the first vacuum hole, wherein each of the two second vacuum holes has a second area A₂, and A₂ is greater than A₁ and less than 2×A₁.

8. The sealing apparatus of claim 7, wherein the plurality of vacuum holes further include:
two third vacuum holes arranged at a side of each of the two second vacuum holes away from the first vacuum hole, wherein each of the two third vacuum holes has a third area A₃, and A₃ is greater than 2×A₁ and less than 3×A₁.

9. The sealing apparatus of claim 3, wherein:
the plurality of vacuum holes are uniformly distributed on the non-vertical sidewall of the head portion.

10. The sealing apparatus of claim 3, wherein a total area of the plurality of vacuum holes is in a range from 10 mm² to 40 mm².

11. The sealing apparatus of claim 3, wherein:
a distance between the backside surface of the stack of wafers and the top surface of the head portion is in a range from 1 mm to 10 mm, and
a distance between the side surface of the stack of wafers and an edge of the head portion in a horizontal direction is in a range from 1 mm to 10 mm.

12. A gas purge device for a sealing apparatus, comprising:
a base portion configured to attach the gas purge device to a wafer stage of the sealing apparatus; and
a head portion configured to engage with the base portion, wherein the head portion includes:
a gas diffusion channel arranged at a top surface of the head portion and configured to direct a purge gas flow toward a backside surface of a stack of wafers; and
a plurality of vacuum holes arranged at a non-vertical sidewall of the head portion and configured to remove sealant particles and purge gas from the sealing apparatus.

13. The gas purge device of claim 12, wherein the gas diffusion channel is an arc-shaped channel, where:
a length of the gas diffusion channel is in a range from 50 mm to 90 mm, and
a central angle of the gas diffusion channel is in a range from 10° to 45°.

14. The gas purge device of claim 12, wherein:
the gas diffusion channel is formed by three vertical sidewalls and the non-vertical sidewall of the head portion, and
the non-vertical sidewall includes a top portion and a bottom portion forming an inward-facing angle.

15. The gas purge device of claim 14, wherein:
the plurality of vacuum holes are arranged at the bottom portion of the non-vertical sidewall.

16. The gas purge device of claim 14, wherein the plurality of vacuum holes include:
a first vacuum hole arranged at a center of the bottom portion of the non-vertical sidewall, wherein the first vacuum hole has a first area A₁;
two second vacuum holes arranged at two sides of the first vacuum hole, wherein each of the two second vacuum holes has a second area A₂; and
two third vacuum holes arranged at a side of each of the two second vacuum holes away from the first vacuum hole, wherein each of the two third vacuum holes has a third area A₃, wherein:
A₂ is greater than A₁ and less than 2×A₁, and
A₃ is greater than 2×A₁ and less than 3×A₁.

17. The gas purge device of claim 12, wherein:
the plurality of vacuum holes are uniformly distributed on the non-vertical sidewall of the head portion.

18. A method for manufacturing a semiconductor device, comprising:
providing a stack of wafers on a wafer stage of a sealing apparatus;
directing, by a nozzle arranged at a side of the wafer stage, a sealant to a side surface of the stack of wafers;
directing, by a gas purger arranged at the side of the wafer stage, a purge gas to a backside surface of the stack of wafers; and
removing sealant particles and the purge gas from the sealing apparatus.

19. The method of claim 18, wherein the gas purger includes a base portion and a head portion, and the method further comprises:
flowing the purge gas through the base portion toward the head portion.

20. The method of claim 19, further comprising:
flowing the purge gas through a gas diffusion channel arranged at a top surface of the head portion toward the backside surface of the stack of wafers; and
removing the sealant particles and the purge gas through a plurality of vacuum holes arranged at a non-vertical sidewall of the head portion.
